(19) United States
(12) Patent Application Publication
(10) Pub. No.: US 2018/0226256 A1
(43) Pub. Date: Aug. 9, 2018

(54) THIN FILM TRANSISTOR, METHOD FOR FABRICATING THE SAME, AND DISPLAY DEVICE

(71) Applicant: BOE Technology Group Co., Ltd., Beijing (CN)

(72) Inventors: Dong Li, Beijing (CN); Xiaolong Li, Beijing (CN); Huijuan Zhang, Beijing (CN)

(21) Appl. No.: 15/716,267

(22) Filed: Sep. 26, 2017

(30) Foreign Application Priority Data
Feb. 4, 2017 (CN) 201710064274.0

(51) Int. Cl. H01L 21/28; H01L 21/3115; H01L 29/66; H01L 21/02

(52) U.S. Cl. CPC H01L 21/28158; H01L 21/31155; H01L 21/02359; H01L 21/02164; H01L 29/66742

(57) ABSTRACT

Disclosed are a thin film transistor, a method for fabricating the same, and a display device, where the fabricating method includes: forming a gate insulation layer on a base substrate; and injecting negative ions into the gate insulation layer through ion injection, wherein the negative ions can be bonded with positive ions in the gate insulation layer. In the fabricating method according to the application, the negative ions can be injected into the gate insulation layer to thereby lower the concentration of positive charges in the gate insulation layer so as to alleviate the threshold voltage in the thin film transistor from negative bias, and also lower power consumption in driving a pixel circuit.

### CROSS-REFERENCE TO RELATED APPLICATION

This application claims priority of Chinese Patent Application No. 201710064274.0, filed on Feb. 4, 2017, which is hereby incorporated by reference in its entirety.

### FIELD

The present application relates to the field of display technologies, and particularly to a thin film transistor, a method for fabricating the same, and a display device.

### BACKGROUND

A Thin Film Transistor (TFT) is a key component in an active driver of a Liquid Crystal Display (LCD), an Organic Light-Emitting Diode (OLED) display, or another display device, where threshold voltage (V₁) which is an important characteristic parameter in the TFT device is voltage between the gate and the source to strongly invert the source terminal in the channel area, and if the voltage between the gate and the source is above the threshold voltage, then the electrically conducting channel will be formed between the source and the drain.

### SUMMARY

Some embodiments of the application provide a method for fabricating a thin film transistor, the method including: forming a gate insulation layer on a base substrate; and injecting negative ions into the gate insulation layer through ion injection, the negative ions can be bonded with positive ions in the gate insulation layer.

Some embodiments of the application further provide a thin film transistor including a gate insulation layer formed on a base substrate; negative ions injected into the gate insulation layer through an ion injection; the negative ions can be bonded with positive ions in the gate insulation layer.

Some embodiments of the application further provide a plurality of the thin film transistors above.

### BRIEF DESCRIPTION OF THE DRAWINGS

FIG. 1 is a first schematic flow chart of a method for fabricating a thin film transistor according to some embodiments of the application;

FIG. 2 is a first schematic structural diagram of a thin film transistor according to some embodiments of the application;

FIG. 3 is a second schematic structural diagram of a thin film transistor according to some embodiments of the application; and

FIG. 4 is a second schematic flow chart of a method for fabricating a thin film transistor according to some embodiments of the application.

### DETAILED DESCRIPTION OF THE EMBODIMENTS

A thin film transistor, a method for fabricating the same, and a display device according to embodiments of the application will be described below in details with reference to the drawings. The thicknesses and shapes of respective film layers in the drawings are not intended to reflect a real proportion, but only intended to illustrate the disclosure of the application.

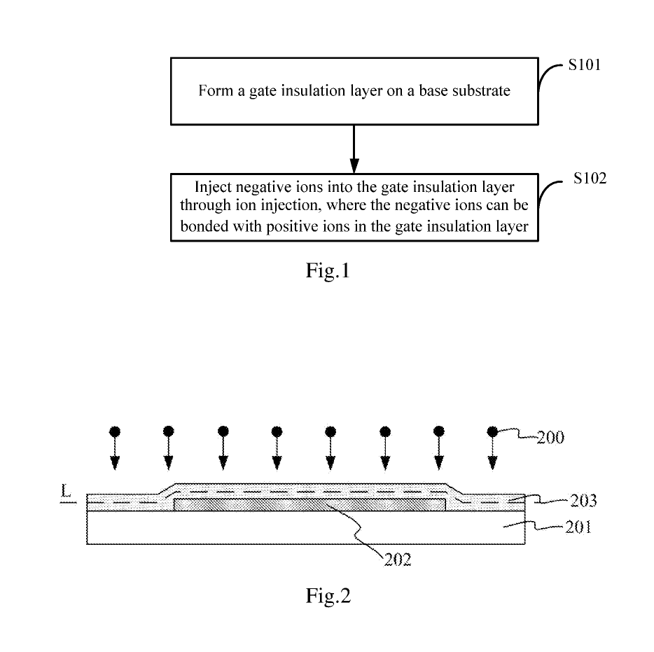

As illustrated in FIG. 1, a method for fabricating a thin film transistor according to some embodiments of the application includes the following steps.

The step S101 is to form a gate insulation layer on a base substrate.

The step S102 is to inject negative ions into the gate insulation layer through ion injection, where the negative ions can be bonded with positive ions in the gate insulation layer.

In the method above for fabricating a thin film transistor according to embodiments of the application, the negative ions are injected into the gate insulation layer so that the concentration of positive charges in the gate insulation layer can be lowered to thereby relieve negative bias for threshold voltage in the thin film transistor from negative bias, so as to lower power consumption in driving a pixel circuit.

The “threshold voltage” as referred to in embodiments is conceptually the same as the “threshold voltage” as appreciated by those skilled in the art, and refers to gate voltage of the thin film transistor when the concentration of electrons on the surface of an active layer is equal to the hole concentration thereon. If there are excessive positive ions in the gate insulation layer, then higher negative voltage will be applied to the gate electrode to thereby form an electrically conducting channel, that is, the threshold voltage of the thin film transistor may be biased negatively due to the excessive positive ions in the gate insulation layer.

In an implementation, the negative ions injected into the gate insulation layer in the step S102 above may be any negative ions as long as they can be boned with positive ions in the gate insulation layer. For example, the negative ions may be boron ions, chlorine ions, etc., or may be other negative ions. The negative ions may be injected at a high concentration. Although the type and the concentration of the negative ions have been exemplified here, they will not be limited thereto. The gate insulation layer may be fabricated of any material with a high dielectric constant, e.g., silicon oxide, silicon nitride, aluminum oxide, etc., and the gate insulation layer may include one or more layers, although the material and the number of layers of the gate insulation layer will not be limited thereto.

In a practical application, the largest amount of negative ions to be injected may be determined according to the drifting amount of the threshold voltage of the thin film transistor, and in order to avoid excessive negative ions from being injected, which would otherwise make the threshold voltage bias positively, the amount of negative ions being injected in reality may be slightly less than the determined largest amount of negative ions to be injected, for example, the amount of actually injected negative ions is 70% to 80% of the largest amount of negative ions to be injected; and while the negative ions are being injected, an ion injecting device may control accurately the amount of injected negative ions as a function of the magnitude of current of the ions, and a period of time for which the ions have been injected, so that the amount of injected negative ions will not exceed the largest amount of negative ions to be injected.

In a practical application, the injection depth of the negative ions can be determined according to the number of layers of the gate insulation layer and the thickness of the gate insulation layer, so there may be a number of implementations of the fabricating method above according to embodiments of the application, several of which will be exemplified below.

In some embodiments, as illustrated in FIG. 2.

The gate insulation layer includes only a first gate insulation layer 203.

The negative ions can be injected into the gate insulation layer through ion injection as follows.

The negative ions are injected into the first gate insulation layer 203 at a depth less than half of the thickness of the first gate insulation layer 203 through ion injection.

Also referring to FIG. 2, the dotted line L as illustrated represents the middle line of a cross section of the first gate insulation layer 203, where the thickness above the dotted line L is equal to that below the dotted line L; and in some embodiments, the negative ions are injected into a position above the dotted line L to thereby avoid a film layer below the first gate insulation layer 203 from being affected by the bombarded negative ions while the negative ions are being injected, for example, the negative ions are bombarded to an interface between the active layer 202 and the first gate insulation layer 203, and even inside the active layer 202, which would otherwise degrade the performance of the active layer 202. It shall be noted that the film layer below the first gate insulation layer 203 may be the active layer 202, or may be the gate, dependent upon whether the thin film transistor is one with a top or bottom gate. The thin film transistor is a thin film transistor with a top gate throughout embodiments of the application, that is, the film layer below the first gate insulation layer 203 is the active layer 202, for example. In some embodiments, the depth at which the negative ions are injected into the first gate insulation layer 203 is less than half of the thickness of the first gate insulation layer 203, that is, the negative ions are injected into a position above the middle of the first gate insulation layer 203, and then the ions are diffused so that the negative ions are diffused into a position below the middle of the first gate insulation layer 203, but also a part of the negative ions are diffused into the interface between the first gate insulation layer 203 and the active layer 202, to thereby lower the concentration of the positive charges in the first gate insulation layer 203, and improving the interface state between the first gate insulation layer 203 and the active layer 202. In an implementation, the depth at which the negative ions are injected into the first gate insulation layer 203 may alternatively be another value, for example, it may alternatively be set to less than ¾ of the thickness of the first gate insulation layer 203, but the depth at which the negative ions are injected into the first gate insulation layer 203 will not be limited to any particular depth in embodiments of the application as long as the film layer below the first gate insulation layer 203 is not affected by the negative ions.

The first gate insulation layer 203 may be fabricated of any material with a high dielectric constant, e.g., silicon oxide, silicon nitride, aluminum oxide, etc., although the material of the gate insulation layer 203 will not be limited thereto.

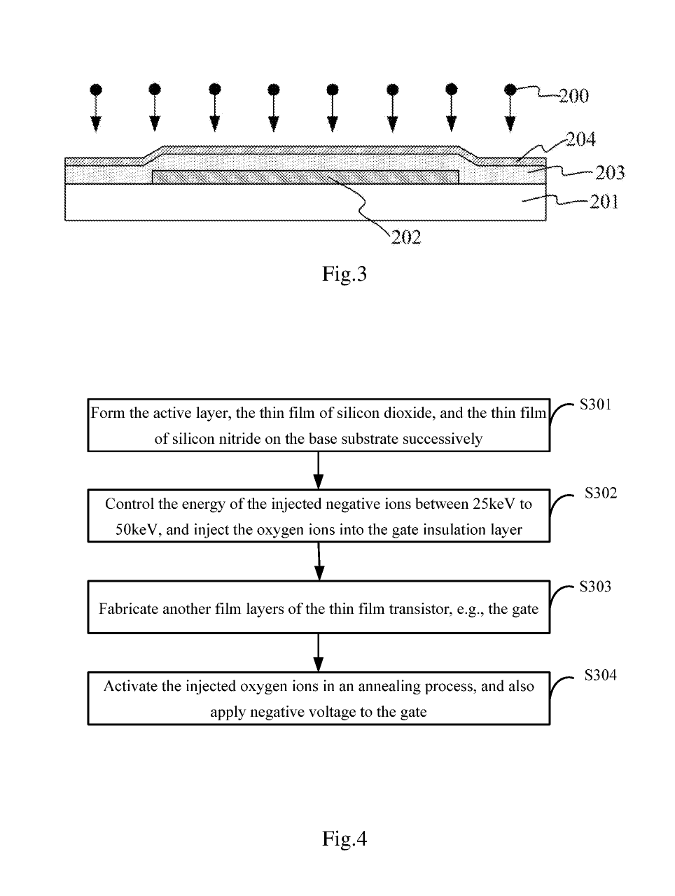

In some embodiments, as illustrated in FIG. 3.

The gate insulation layer includes a first gate insulation layer 203, and a second gate insulation layer 204 located on the side of the first gate insulation layer 203 away from the base substrate.

The negative ions can be injected into the gate insulation layer through ion injection as follows.

After the second gate insulation layer 204 is formed, the negative ions are injected into the gate insulation layer through ion injection.

The depth at which the negative ions are injected into the gate insulation layer is less than half of the total thickness of the first gate insulation layer 203 and the second gate insulation layer 204.

Referring to FIG. 3, in order to avoid a film layer below the gate insulation layer from being affected by the injected negative ions, the depth at which the negative ions are injected into the gate insulation layer is less than half of the total thickness of the first gate insulation layer 203 and the second gate insulation layer 204. In a practical application, the depth at which the negative ions are injected into the gate insulation layer may alternatively be another value, for example, it may alternatively be set to less than ¾ of the total thickness of the first gate insulation layer 203 and the second gate insulation layer 204, but the depth at which the negative ions are injected into the first gate insulation layer 203 will not be limited to any particular depth in the embodiment of the application as long as the film layer below the first gate insulation layer 203 is not affected by the negative ions. In a practical application, the injection depth of the negative ions may also be determined according to the position where the positive charges are concentrated, for example, if the positive charges being concentrated primarily at the second gate insulation layer 204 are detected, then the injection depth of the negative ions may be set smaller, and if the positive charges being concentrated primarily at the first gate insulation layer 203 are detected, then the injection depth of the negative ions may be set larger.

In some embodiments, as illustrated in FIG. 3.

The gate insulation layer includes a first gate insulation layer 203, and a second gate insulation layer 204 located on the side of the first gate insulation layer 203 away from the base substrate.

The negative ions can be injected into the gate insulation layer through ion injection as follows.

After the first gate insulation layer 203 is formed, and before the second gate insulation layer 204 is formed, the negative ions are injected into the first gate insulation layer 203 through ion injection.

The depth at which the negative ions are injected into the gate insulation layer is less than half of the thickness of the first gate insulation layer 203.

This can be applicable to the case that the positive charges are concentrated primarily at the first gate insulation layer 203. In this case, firstly the negative ions are injected into the first gate insulation layer 203, and then the second gate insulation layer 204 is fabricated, thus making it easier for the negative ions to be bonded with the positive charges in the first gate insulation layer 203, and also lowering the energy for injecting ions. Furthermore the depth at which the negative ions are injected into the first gate insulation layer 203 is less than half of the thickness of the first gate insulation layer 203, this is also done in order to avoid a film layer below the first gate insulation layer 203 from being affected, so a repeated description thereof will be omitted here. In an implementation, the depth at which the negative ions are injected into the first gate insulation layer 203 may alternatively be another value, for example, it may alternatively be set to less than ¾ of the thickness of the first gate insulation layer 203, but the depth at which the negative ions are injected into the first gate insulation layer 203 will not be limited to any particular depth in embodiments of the application as long as the film layer below the first gate insulation layer 203 is not affected by the negative ions.

For the thin film transistor with a top gate, the first gate insulation layer 203 is closer to the electrically conducting channel, and generally if there is a shorter distance of the first gate insulation layer 203 from the electrically conducting channel, then the threshold voltage will be more affected, so generally there are superfluous positive charges in the first gate insulation layer 203, thus tending to make the threshold voltage of the thin film transistor bias negatively. Thus the negative ions can be injected in any order, for example firstly the second gate insulation layer 204 may be fabricated, and then the negative ions may be injected, or firstly the negative ions may be injected, and then the second gate insulation layer 204 may be fabricated.

Furthermore in some embodiments, the first gate insulation layer 203 is a thin film of silicon dioxide.

In a practical application, a predominant component of the thin film of silicon dioxide is SiO₂, but since there may be dangling bonds of silicon atoms in the thin film of silicon dioxide, there may be other components of SiO, Si, or the like in the thin film of silicon dioxide. The dangling bonds of the silicon atoms make these atoms appear with positive charges, and if there are excessive positive charges in the thin film of silicon dioxide, then the electrically conducting channel of the thin film transistor may be hindered from being formed. Furthermore the second gate insulation layer 204 may be fabricated of any material with a high dielectric constant, e.g., silicon oxide, silicon nitride, aluminum oxide, etc., although the material of the second gate insulation layer will not be limited thereto.

It shall be noted that in FIG. 2 and FIG. 3, a black circle 200 represents a negative ion, and an arrow represents a direction in which the negative ion 200 is injected, only for the purpose of illustrating embodiments of the application conveniently, but not suggesting the real size of the negative charge 200.

Embodiments of the application have been described only by way of an example in which the gate insulation layer includes only the first gate insulation layer 203, or the gate insulation layer includes the first gate insulation layer 203 and the second gate insulation layer 204, but in an implementation, the gate insulation layer may alternatively include more film layers as needed in practice, and the depth at which, and the position where the negative ions are injected will be determined according to the position where the positive charges are concentrated, and the thicknesses of the respective film layers in the gate insulation layer, although the number of film layers in the gate insulation layer will not be limited to any particular number of film layers in embodiments of the application.

Optionally in the method above for fabricating a thin film transistor according to embodiments of the application, the negative ions are injected into the gate insulation layer through ion injection as follows.

The energy for injecting the negative ions into the gate insulation layer is controlled between 25 keV to 50 keV.

In a practical application, for the gate insulation with a varying thickness, the injection position of the negative ions can be controlled by adjusting the energy for injecting the negative ions, where higher the energy for injecting the negative ions is, larger the thickness at which the negative ions is injected is.

Furthermore in the method above for fabricating a thin film transistor according to embodiments of the application, after the negative ions are injected into the gate insulation layer through ion injection, the method can further include.

Activating the injected negative ions.

The injected negative ions can be activated to thereby greatly improve the activity of the negative ions so as to facilitate diffusion of the negative ions so that more dangling bonds of the silicon atoms are filled up with the negative ions, thus lowering the concentration of the positive charges. For example, 100 negative ions are injected into the thin film of silicon dioxide, and if they are not activated, then there may be approximately 50 negative ions to fill up the dangling bonds of the silicon atoms, and if they are activated, then there may be the majority of the injected negative ions, for example, approximately 90 (and even 100) negative ions, to fill up the dangling bonds of the silicon atoms.

Optionally the injected negative ions may be activated as follows.

The injected negative ions are activated in an annealing process.

In an implementation, negative ions may alternatively be activated in another process, although embodiments of the application will not be limited to any particular process for activating the negation ions.

Optionally the injected negative ions may be activated in an annealing process as follows.

Temperature of the annealing process is controlled between 100° C. and 400° C., or 200° C.

In the annealing process, if the temperature is higher, then the activity of the negation ions may be higher, but the temperature optionally ranges from 100° C. to 400° C., or 200° C., because it is impossible to infinitely raise the temperature of the annealing process taking into account the temperature bearable to the think film transistor device.

Optionally in the method above for fabricating a thin film transistor according to embodiments of the application, before the injected negative ions are activated, a gate is formed on the base substrate 201.

Negative voltage is applied to the gate while the injected negative ions are being activated, or after the injected negative ions are activated.

The negative voltage can be applied to the gate to thereby further facilitate diffusion of the negative ions to around the interface between the thin film of silicon dioxide and the active layer 202 to fill up the dangling bonds of superfluous silicon in the thin film of silicon dioxide and at the interface so as to lower the concentration of the positive charges, to enhance the robustness of the gate insulation layer against a breakthrough, and to improve the interface state between the thin film of silicon dioxide and the active layer 202.

In an implementation, the negative voltage can be applied to the gate while the negative ions are being activated, or after the negative ions are activated, and the negative voltage is applied to the gate while the negative ions are being activated, so that on one hand, the diffusion speed of the negative ions can be improved for a better effect of filling up the dangling bonds of superfluous silicon, and on the other hand, a processing period of time can be saved because the two operations are performed concurrently. The negative ions can be activated, and the negative voltage can be applied to the gate, while the thin film transistor is being fabricated, or after the thin film transistor is fabricated, and the negative ions are activated, and the negative voltage is applied to the gate, after the thin film transistor is fabricated, so that the thin film transistor will not be hindered from being fabricated.

In a practical application, before the gate insulation layer is fabricated, a buffer layer and an active layer 202 can be fabricated on the base substrate 201 in deposition, crystallization, etching, and other processes, and the order in which the gate and the active layer 202 are fabricated needs to be determined dependent upon whether the thin film transistor is a thin film transistor with a bottom or top gate. The thin film transistor with a top gate will be described as an example throughout embodiments of the application, where the film layer below the gate insulation layer is the active layer 202, although the type of the thin film transistor will not be limited thereto.

Optionally the negative voltage can be applied to the gate as follows.

The negative voltage of 20V to 50V, or negative voltage 30V is applied to the gate.

In a practical application, in the method above for fabricating a thin film transistor according to embodiments of the application, the negative ions can be injected into the gate insulation layer through ion injection particularly as follows.

Oxygen ions are injected into the gate insulation layer through ion injection.

The gate insulation layer generally includes a thin film of silicon dioxide, and the negative ions injected into the gate insulation layer is optionally oxygen ions to thereby improve the atom ratio of the oxygen ions to the silicon ions in the thin film of silicon dioxide, and also make the thin film of silicon dioxide more compact and firm due to thermal treatment in an anneal process so as to fill up the dangling bonds of the silicon atoms, to lower the concentration of the positive charges, and to enhance the robustness of the gate insulation layer against a breakthrough.

Some embodiments of the embodiment of the application will be described below with reference to FIG. 3 and FIG. 4 by way of an example in which a thin film transistor with a top gate includes a gate insulation layer including a thin film of silicon dioxide, and a thin film of silicon nitride, that is, the first gate insulation layer 203 is the thin film of silicon dioxide, and the second gate insulation layer 204 is the thin film of silicon nitride.

The step S301 is to form the active layer 202, the thin film of silicon dioxide, and the thin film of silicon nitride on the base substrate 201 successively;

The step S302 is to control the energy for injecting the negative ions between 25 keV to 50 keV, and to inject the oxygen ions into the gate insulation layer, where the injected oxygen ions are concentrated primarily above the middle of the thin film of silicon dioxide;

Generally there are some ions in the thin film of silicon nitride, where the ions can fill up the dangling bonds of the silicon atoms in the thin film of silicon nitride; and the thin film of silicon dioxide is closer to the electrically conducting channel, and generally if there is a shorter distance of the thin film of silicon dioxide from the electrically conducting channel, then the threshold voltage will be more affected, so it is primarily the thin film of silicon dioxide that makes the threshold voltage of the thin film transistor bias negatively. Thus the injected oxygen ions are controlled to be concentrated primarily above the middle of the thin film of silicon dioxide, that is, the depth at which the oxygen ions are injected into the thin film of silicon dioxide is less than half of the thickness of the thin film of silicon dioxide.

The step S303 is to fabricate another film layers of the thin film transistor, e.g., the gate.

The step S304 is to activate the injected oxygen ions in an annealing process, and also apply negative voltage to the gate, where the temperature of the annealing process is controlled at approximately 200° C., and the negative voltage applied to the gate is controlled at approximately 30V.

Based upon the same inventive idea, some embodiments of the application provide a thin film transistor fabricated using the fabricating method above. Since the thin film transistor addresses the problem under a similar principle to the method above for fabricating a thin film transistor, reference can be made to the implementation of the method above for fabricating a thin film transistor for an implementation of the thin film transistor, so a repeated description thereof will be omitted here.

Based upon the same inventive idea, some embodiments of the application provide a display device including a plurality of the thin film transistors above, where the display device can be a mobile phone, a tablet computer, a TV set, a display, a notebook computer, a digital photo frame, a navigator, or any other product or component capable of displaying. Since the display device addresses the problem under a similar principle to the thin film transistor above, reference can be made to the implementation of the thin film transistor above for an implementation of the thin film transistor, so a repeated description thereof will be omitted here.

In the thin film transistor, the method for fabricating the same, and the display device above according to the embodiments of the application, oxygen ions, are injected into the gate insulation layer so that the gate insulation layer includes the thin film of silicon dioxide to thereby improve the atom ratio of the oxygen atoms to the silicon atoms in the thin film of silicon dioxide; and the oxygen ions s can be activated, and the voltage can be applied to the gate, so that the oxygen ions are diffused to around the interface between the thin film of silicon dioxide and the active layer to thereby fill up the dangling bonds of the superfluous silicon in the thin film of silicon dioxide so as to lower the concentration of the positive ions, thus relieving the threshold voltage in the thin film transistor from negative bias to thereby lower power consumption in driving a pixel circuit, and also improving the interface state between the thin film of silicon dioxide and the active layer, and enhancing the robustness of the gate insulation layer against a breakthrough.

Evidently those skilled in the art can make various modifications and variations to the application without departing from the spirit and scope of the application. Accordingly the application is also intended to encompass these modifications and variations thereto so long as the modifications and variations come into the scope of the claims appended to the application and their equivalents.

1. A method for fabricating a thin film transistor, the method comprises:
forming a gate insulation layer on a base substrate; and
injecting negative ions into the gate insulation layer through an ion injection, wherein the negative ions can be bonded with positive ions in the gate insulation layer.

2. The method according to claim 1, wherein the gate insulation layer comprises only a first gate insulation layer; and
the injecting negative ions into the gate insulation layer through the ion injection comprises:
injecting negative ions into the first gate insulation layer through the ion injection at a depth less than a half of the thickness of the first gate insulation layer.

3. The method according to claim 1, wherein the gate insulation layer comprises a first gate insulation layer, and a second gate insulation layer located on a side of the first gate insulation layer away from the base substrate; and
the injecting negative ions into the gate insulation layer through the ion injection comprises:
injecting negative ions into the gate insulation layer through the ion injection after the second gate insulation layer is formed;
wherein a depth at which the negative ions are injected into the gate insulation layer is less than a half of the total thickness of the first gate insulation layer and the second gate insulation layer.

4. The method according to claim 1, wherein the gate insulation layer comprises a first gate insulation layer, and a second gate insulation layer located on a side of the first gate insulation layer away from the base substrate; and
the injecting negative ions into the gate insulation layer through the ion injection comprises:
injecting negative ions into the first gate insulation layer through the ion injection after the first second gate insulation layer is formed, and before the second gate insulation layer is formed;
wherein a depth at which the negative ions are injected into the first gate insulation layer is less than a half of the thickness of the first gate insulation layer.

5. The method according to claim 3, wherein the first gate insulation layer is a thin film of silicon dioxide.

6. The method according to claim 1, wherein the injecting negative ions into the gate insulation layer through the ion injection comprises:
controlling an energy for injecting the negative ions into the gate insulation layer between 25 keV to 50 keV.

7. The method according to claim 1, wherein after the negative ions are injected into the gate insulation layer through the ion injection, the method further comprises:
activating injected negative ions.

8. The method according to claim 7, wherein the activating the injected negative ions comprises:
activating the injected negative ions in an annealing process.

9. The method according to claim 8, wherein the activating the injected negative ions in an annealing process comprises:
controlling a temperature of the annealing process between 100° C. and 400° C.

10. The method according to claim 7, further comprising: forming a gate on the base substrate before the injected ions are activated; and
applying a negative voltage to the gate while the injected ions are being activated, or after the injected ions are activated.

11. The method according to claim 10, wherein the applying negative voltage to the gate comprises:
applying a negative voltage ranging from 20V to 50V to the gate.

12. The method according to claim 1, wherein the injecting negative ions into the gate insulation layer through the ion injection comprises:
injecting oxygen ions into the gate insulation layer through the ion injection.

13. A thin film transistor, comprising:
a gate insulation layer formed on a base substrate;
negative ions injected into the gate insulation layer through an ion injection;
wherein the negative ions can be bonded with positive ions in the gate insulation layer.

14. The thin film transistor according to claim 13, wherein the gate insulation layer comprises only a first gate insulation layer; and
the injecting negative ions into the gate insulation layer through the ion injection comprises:
a depth at which the negative ions are injected into the first gate insulation layer is less than a half of the thickness of the first gate insulation layer.

15. The thin film transistor according to claim 13, wherein the gate insulation layer comprises a first gate insulation layer, and a second gate insulation layer located on a side of the first gate insulation layer away from the base substrate; and
the negative ions are injected into the gate insulation layer through the ion injection after the second gate insulation layer is formed;
a depth at which the negative ions are injected into the gate insulation layer is less than a half of the total thickness of the first gate insulation layer and the second gate insulation layer.

16. The thin film transistor according to claim 13, wherein the gate insulation layer comprises a first gate insulation layer, and a second gate insulation layer located on a side of the first gate insulation layer away from the base substrate; and
the negative ions are injected into the first gate insulation layer through the ion injection after the first second gate insulation layer is formed, and before the second gate insulation layer is formed;
a depth at which the negative ions are injected into the first gate insulation layer is less than a half of the thickness of the first gate insulation layer.

17. The thin film transistor according to claim 15, wherein the first gate insulation layer is a thin film of silicon dioxide.

18. The thin film transistor according to claim 13, wherein the negative ions are injected into the gate insulation layer by an energy between 25 keV to 50 keV.

19. The thin film transistor according to claim 13, wherein injected negative ions are activated.

20. A display device, comprising a plurality of the thin film transistors according to claim 13.
